(19) United States
(12) Patent Application Publication
(10) Pub. No.: US 2025/0062305 A1
(43) Pub. Date: Feb. 20, 2025

(54) ELECTRONIC DEVICE AND MANUFACTURING METHOD THEREOF

(71) Applicant: InnoLux Corporation, Miao-Li County (TW)

(72) Inventors: Ting-Wei LIANG, Miao-Li County (TW); Jiunn-Shyong LIN, Miao-Li County (TW); I-An YAO, Miao-Li County (TW)

(21) Appl. No.: 18/775,515

(22) Filed: Jul. 17, 2024

(30) Foreign Application Priority Data
Aug. 17, 2023 (CN) 202311039697.9

(51) Int. Cl. H01L 25/18; H01L 25/00

(52) U.S. Cl. CPC H01L 25/18; H01L 25/50

(57) ABSTRACT

A manufacturing method manufactures an electronic device, and includes the steps of: providing a first temporary panel including a first carrier board, a first substrate, a second substrate and a second carrier board arranged in sequence; providing a second temporary panel including a third carrier board, a third substrate, a fourth substrate and a fourth carrier board arranged in sequence; and removing the second carrier board and the third carrier board, and fixing the second substrate and the third substrate with an attaching member.

### CROSS-REFERENCE TO RELATED APPLICATIONS

This application claims the benefits of the Chinese Patent Application Serial Number 202311039697.9, filed on Aug. 17, 2023, the subject matter of which is incorporated herein by reference.

### BACKGROUND

### Field of the Disclosure

The present disclosure relates to a manufacturing method of an electronic device and an electronic device manufactured using the method and, more particularly, to an electronic device including a plurality of panels and a manufacturing method thereof.

### Description of Related Art

With the continuous advancement of technology related to electronic devices, the electronic products are developing towards being thin and light. When an electronic device includes multiple panels, the overall thickness and weight will be increased. Therefore, there is an urgent need to provide an electronic device and a manufacturing method thereof so as to optimize the electronic device and the manufacturing process thereby realizing a thin electronic device.

### SUMMARY

The present disclosure provides a manufacturing method of an electronic device, which comprises the steps of: providing a first temporary panel, wherein the first temporary panel includes a first carrier board, a first substrate, a second substrate and a second carrier board arranged in sequence; providing a second temporary panel, wherein the second temporary panel includes a third carrier board, a third substrate, a fourth substrate and a fourth carrier board arranged in sequence; and removing the second carrier board and the third carrier board, and fixing the second substrate and the third substrate with an attaching member.

The present disclosure also provides an electronic device, which comprises: a supporting component; a first panel disposed on the supporting component, wherein the first panel includes a first substrate having a display area and a peripheral circuit area; and a second panel disposed on the first panel, wherein the supporting component overlaps the display area and at least a portion of the peripheral circuit area of the first substrate, and the supporting component has a thickness greater than that of the first substrate.

Other novel features of the disclosure will become more apparent from the following detailed description when taken in conjunction with the accompanying drawings.

### BRIEF DESCRIPTION OF DRAWINGS

FIG. 1A, 1B-1, 1B-2, and 1C-1G are schematic flow diagrams illustrating a manufacturing method of an electronic device according to an embodiment of the present disclosure;

FIG. 2A and FIG. 2B are respectively enlarged views of a portion of FIG. 1B-2;

FIG. 3 is a schematic cross-sectional view of an electronic device according to an embodiment of the present disclosure;

FIG. 4 is a schematic three-dimensional view of an electronic device according to an embodiment of the present disclosure;

FIG. 5A is a schematic cross-sectional view of an electronic device according to an embodiment of the present disclosure;

FIG. 5B is an enlarged view of a portion of FIG. 5A;

FIG. 6 is a schematic cross-sectional view of an electronic device according to an embodiment of the present disclosure; and

FIG. 7 is a schematic cross-sectional view of an electronic device according to an embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. Furthermore, in the specification and claims, unless otherwise specified, ordinal numbers, such as “first”, “second”, etc., used herein are intended to distinguish elements rather than disclose explicitly or implicitly that names of the elements bear the wording of the ordinal numbers. The ordinal numbers do not imply what order an element and another element are in terms of space, time or steps of a manufacturing method.

In the entire specification and the appended claims of the present disclosure, certain words are used to refer to specific components. Those skilled in the art should understand that electronic device manufacturers may refer to the same components by different names. The present disclosure does not intend to distinguish those components with the same function but different names. In the claims and the following description, the words “comprise”, “include” and “have” are open type language, and thus they should be interpreted as meaning “including but not limited to”. Therefore, when the terms “comprise”, “include” and/or “have” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between.

It is noted that the following are exemplary embodiments of the present disclosure, but the present disclosure is not limited thereto, while a feature of some embodiments can be applied to other embodiments through suitable modification, substitution, combination, or separation. In addition, the present disclosure can be combined with other known structures to form further embodiments.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the distance and thickness may be measured using an optical microscope, and the distance and thickness may be obtained by measuring a cross-sectional image in an electron microscope, but the present disclosure is not limited thereto. In addition, there may be certain errors between any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

The embodiments of the present disclosure may be understood together with the drawings, and the drawings of the present disclosure are also regarded as part of the disclosure description. It should be understood that the drawings of the present disclosure are not in scale and, in fact, the dimensions of elements may be arbitrarily enlarged or reduced in order to clearly illustrate features of the present disclosure.

Furthermore, when mentioning that a first material layer is disposed on or above a second material layer, it may include the situation where the first material layer and the second material layer are in direct contact or the first material layer and the second material layer may not in direct contact, that is, there may be one or more layers of other materials disposed between the first material layer and the second material layer. However, if the first material layer is directly disposed on the second material layer, it means that the first material layer and the second material layer are in direct contact.

In some embodiments of the present disclosure, terms related to joining and connecting, such as “connection”, “interconnection”, etc., unless otherwise defined, may mean that two structures are in direct contact, or may also mean that the two structures are not in direct contact in which other structures are disposed between the two structures. Moreover, the terms related to joining and connecting may also include the situation where both structures are movable, or both structures are fixed. In addition, the terms “electrical connecting” or “coupling” include any direct and indirect means of electrical connection.

It should be noted that the technical solutions provided in different embodiments below may be replaced, combined or mixed with each other to constitute another embodiment without violating the spirit of the present disclosure.

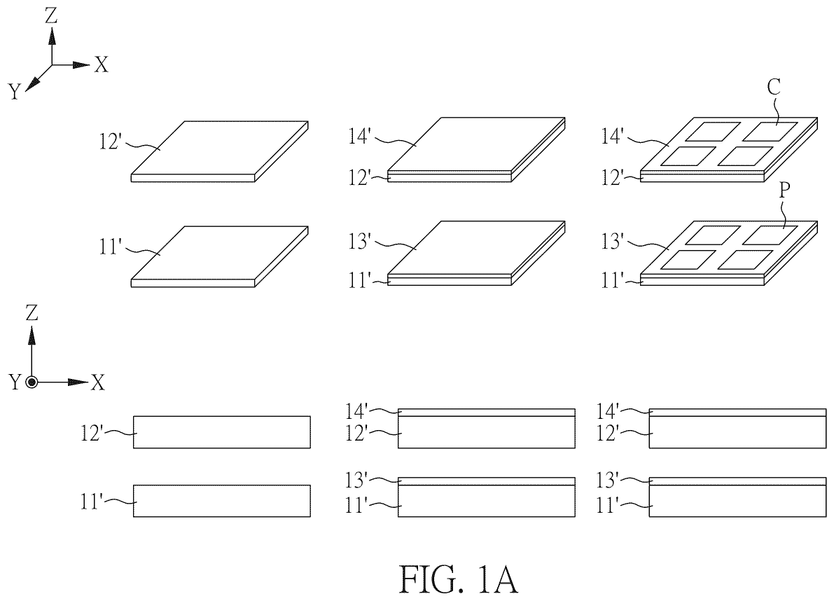

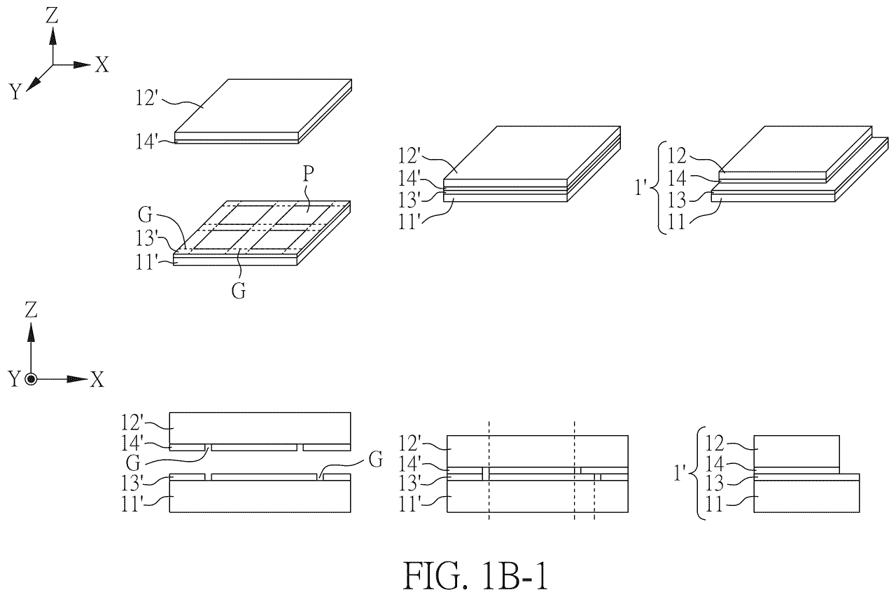

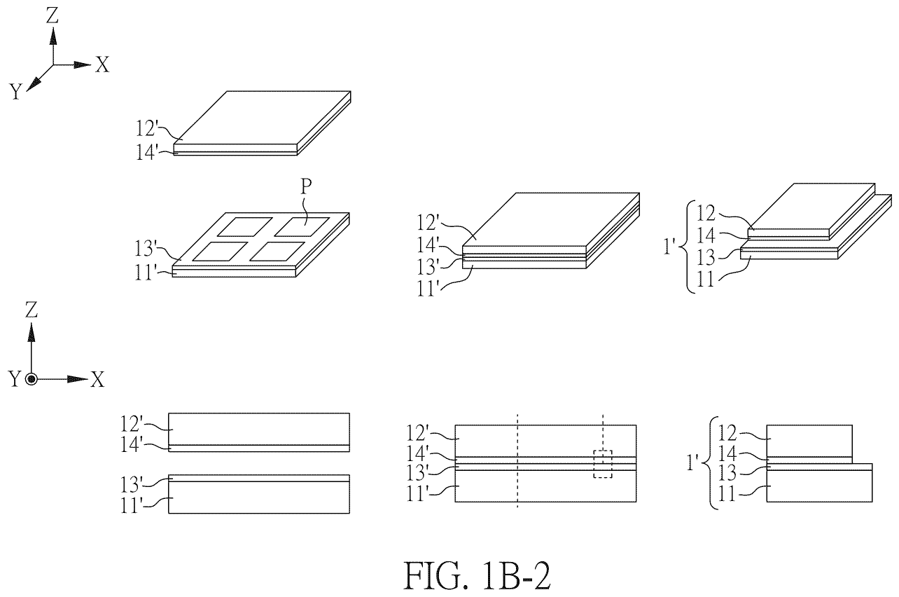

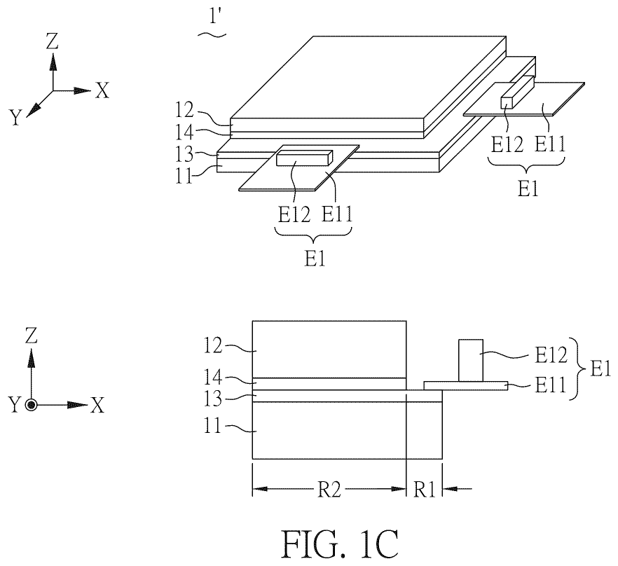

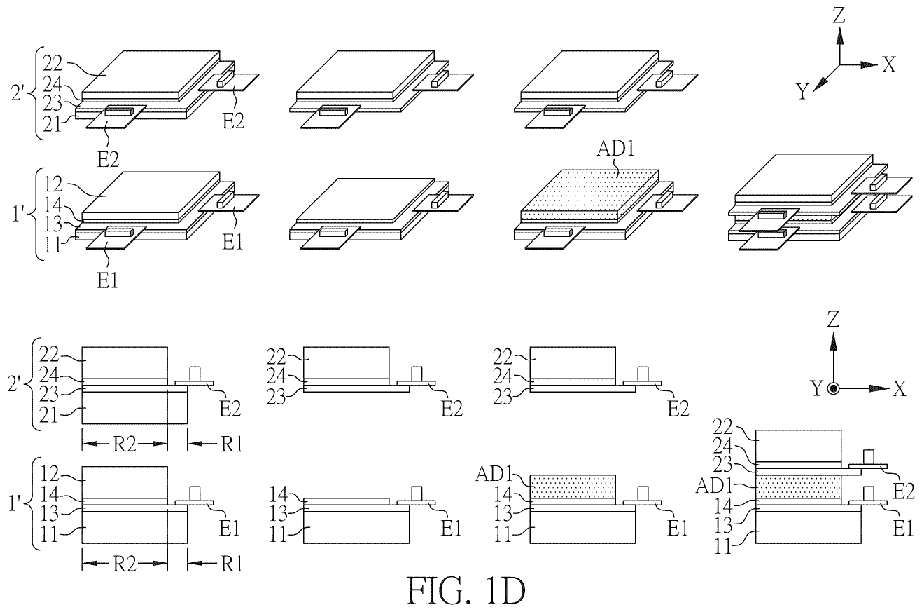

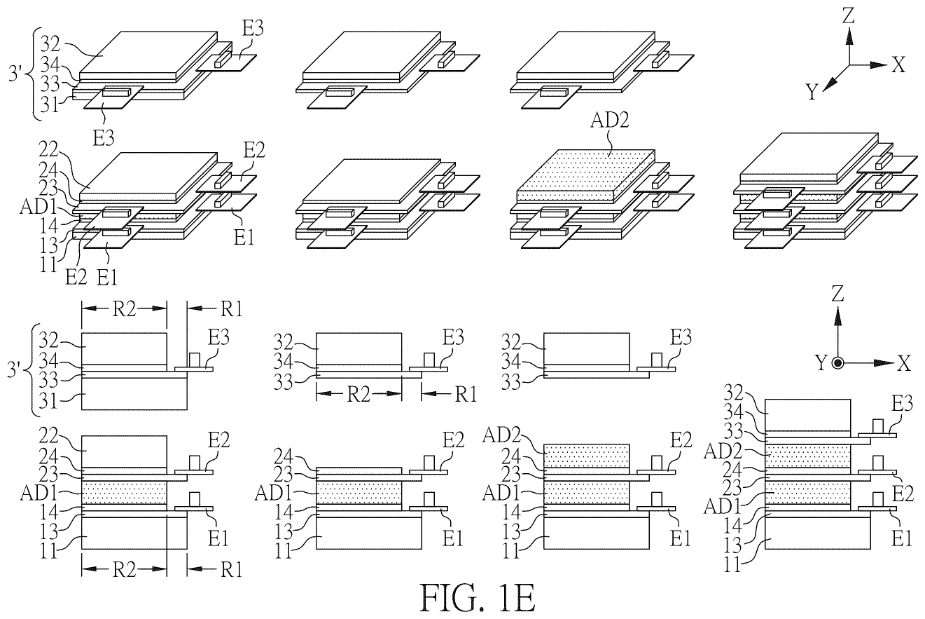

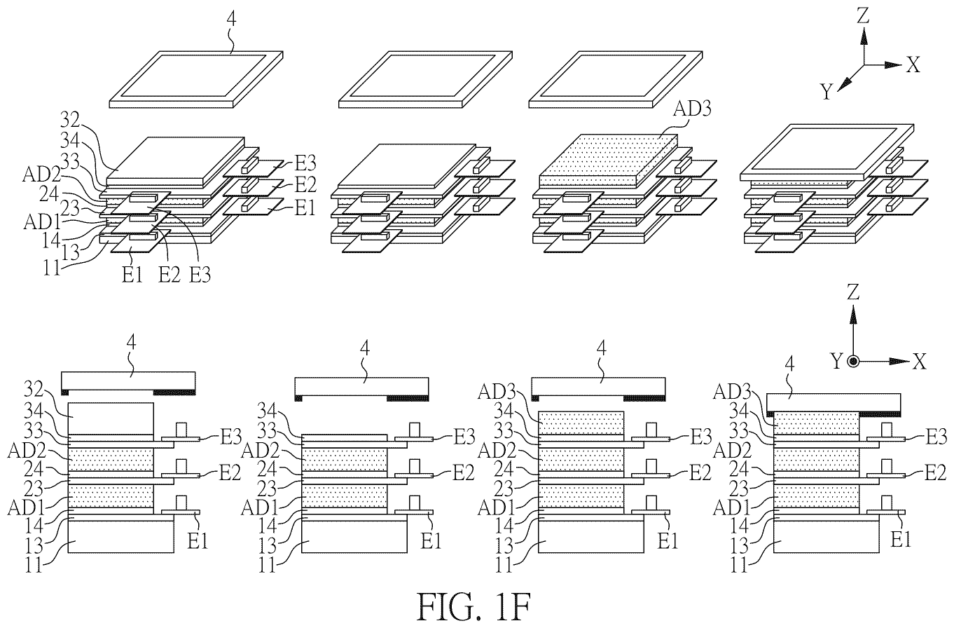

FIG. 1A to FIG. 1G are schematic flow diagrams illustrating a manufacturing method of an electronic device according to an embodiment of the present disclosure, wherein the upper half of each figure is a schematic three-dimensional view, the lower half thereof is a schematic cross-sectional view and, for convenience of explanation, some components of the electronic device are omitted from the schematic views.

In one embodiment of the present disclosure, as shown in FIG. 1A, in the manufacturing method of an electronic device, a first mother carrier board 11′ and a second mother carrier board 12′ are provided. A first mother substrate 13′ is disposed on the first mother carrier board 11′, and a second mother substrate 14′ is disposed on the second mother carrier board 12′. Next, pixel arrays P are disposed on the first mother substrate 13′, and color filter units C are disposed on the second mother substrate 14′. However, the present disclosure is not limited thereto. In other implementations (not shown), both the pixel arrays P and the color filter units C may be disposed on the first mother substrate 13′. Although not shown in the figure, in one embodiment, a peeling layer (not shown) may be selectively disposed between the first mother substrate 13′ and the first mother carrier board 11′ or a peeling layer (not shown) may be selectively disposed between the second mother substrate 14′ and the second mother carrier board 12′. As a result, the subsequent separation step of the carrier board and the substrate may be facilitated.

In one embodiment, the material of the first mother carrier board 11′ and/or the second mother carrier board 12′ may include glass, quartz, sapphire, ceramics, plastic, other suitable substrate materials or a combination thereof, but the present disclosure is not limited thereto. The materials of the first mother substrate 13′ and the second mother substrate 14′ may each include polycarbonate (PC), polyimide (PI), polypropylene (PP), polyethylene terephthalate (PET), polymethylmethacrylate (PMMA), other suitable materials or a combination thereof, but the present disclosure is not limited thereto. In one embodiment, the hardness and/or thickness of the first mother carrier board 11′ and/or the second mother carrier board 12′ are, for example, greater than the hardness and/or thickness of the first mother substrate 13′ and/or the second mother substrate 14′. In some embodiments, the peeling layer (not shown) may include adhesive, epoxy resin, die attach film (DAF), other similar materials, or a combination thereof, but the present disclosure is not limited thereto.

In one embodiment, as shown in FIG. 1B-1, the manufacturing method of an electronic device may further include: pre-cutting the first mother substrate 13′ and the second mother substrate 14′ to form a plurality of grooves G (which may be through grooves or non-through grooves) on the first mother substrate 13′ and the second mother substrate 14′, respectively, so as to reduce the risk of damage during subsequent cutting steps. Next, not shown in the figure, a display layer (not shown, for example, but not limited to, a liquid crystal layer) is disposed on the first mother substrate 13′ or the second mother substrate 14′. The display layer (not shown) is disposed by one drop filling (ODF) process technology, for example. Subsequently, the first mother carrier board 11′ and the first mother substrate 13′ are assembled with the second mother carrier board 12′ and the second mother substrate 14′. For example, the first mother substrate 13′ is assembled with the second mother substrate 14′ through a frame sealant (not shown), and the frame sealant (not shown) is, for example, disposed between the first mother substrate 13′ and the second mother substrate 14′, and surrounds the display layer (not shown). Then, the first mother carrier board 11′ and the second mother carrier board 12′ are cut, for example, the first mother carrier board 11′ and the second mother carrier board 12′ may be cut along the dotted line in FIG. 1B-1 to separate parts of the first mother carrier board 11′ and the second mother carrier board 12′ so as to form a plurality of first temporary panels 1′. The first temporary panel 1′ may include a first carrier board 11, a first substrate 13, a second substrate 14 and a second carrier board 12 arranged in sequence.

In the present disclosure, the pre-cutting step and the cutting step may each be performed by laser cutting, wheel knife cutting or a combination thereof.

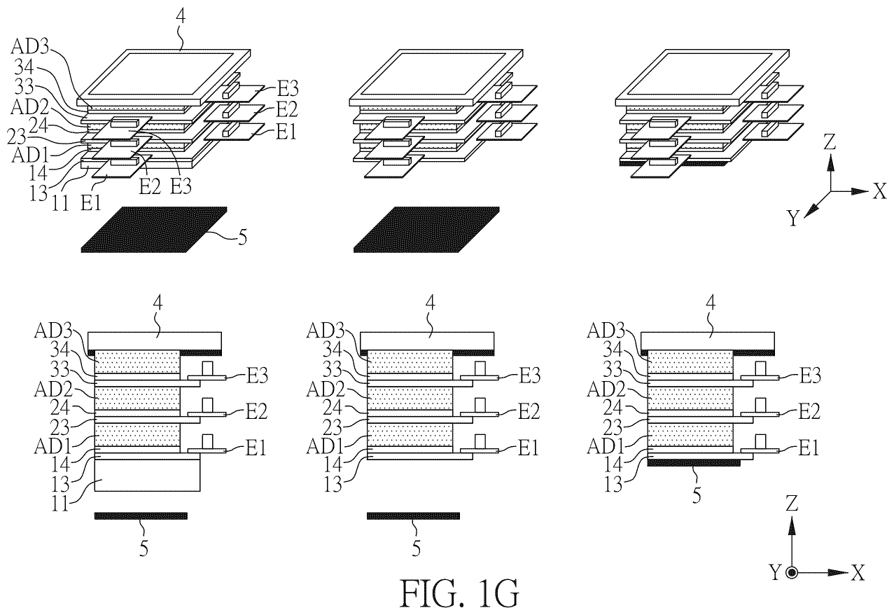

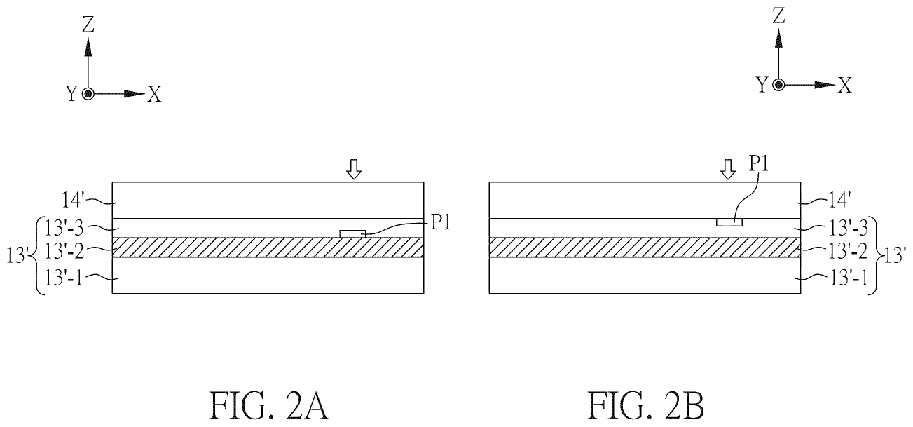

In another implementation aspect, as shown in FIG. 1B-2, after the steps of disposing the pixel arrays P on the first mother substrate 13′ and the color filter units C on the second mother substrate 14′, the pre-cutting step of the first mother substrate 13′ and the second mother substrate 14′ may be omitted (that is, for example, the pre-cutting step in FIG. 1B-1 is omitted) and, after disposing a display layer (not shown) on the first mother substrate 13′ or the second mother substrate 14′, the first mother carrier board 11′ and the first mother substrate 13′ are assembled with the second mother carrier board 12′ and the second mother substrate 14′. Subsequently, the first mother carrier board 11′, the first mother substrate 13′, the second mother carrier board 14′ and the second mother carrier board 12′ are cut, which may be performed by, for example, cutting the first mother carrier board 11, the first mother substrate 13′, the second mother substrate 14′ and/or the second mother carrier board 12′ along the dotted line in FIG. 1B-2 so as to form a plurality of first temporary panels l′. The first temporary panel l′ includes a first carrier board 11, a first substrate 13, a second substrate 14 and a second carrier board 12 arranged in sequence. The aforementioned cuttings of the first mother carrier board 11′, the first mother substrate 13′, the second mother substrate 14′ and the second mother carrier board 12′ may be completed in different cutting procedures, and the cutting method is not limited to wheel knife cutting or laser cutting.

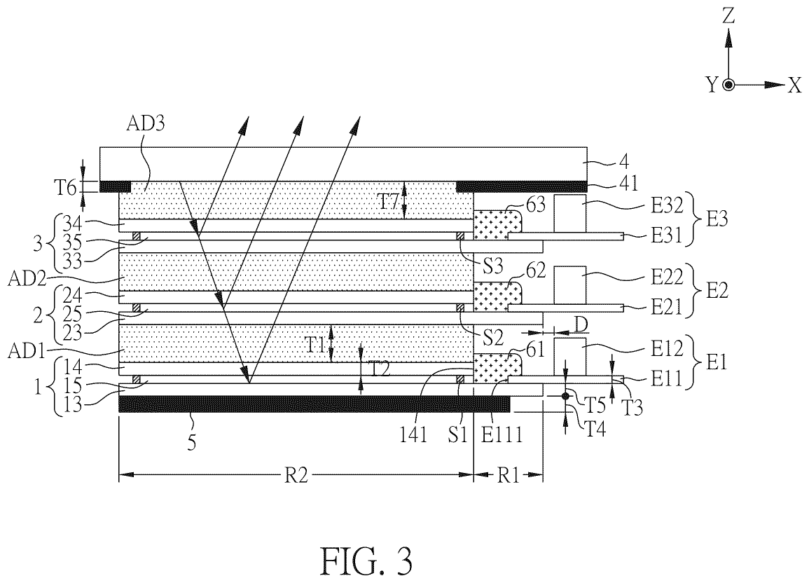

In one embodiment of the present disclosure, as shown in FIG. 1C, the first substrate 13 has a peripheral circuit area R1 and, before the step of removing the second carrier board 12, it may further include the step of disposing a first electronic component E1 on the peripheral circuit area R1 of the first substrate 13. Therefore, the first temporary panel 1′ may further include a first electronic component E1 disposed on the peripheral circuit area R1 of the first substrate 13. In more detail, as shown in FIG. IC, the first substrate 13 includes a peripheral circuit area R1 and a display area R2. In the normal direction Z (top view direction) of the electronic device, there area where the first substrate 13 and the second substrate 14 do not overlap is defined as the peripheral circuit area R1, and the area where the first substrate 13 and the second substrate 14 overlap is defined as the display area R2. In other embodiments, the display area R2 may be replaced by other active areas (such as a detection area, a touch area, or other suitable areas). In one embodiment, as shown in FIG. 1C, two first electronic components E1 may be disposed on the peripheral circuit area R1 of the first substrate 13 to respectively transmit or receive gate line and data line signals. The two electronic components E1 may be, for example, disposed on different sides of the peripheral circuit area R1, but the present disclosure is not limited thereto. In other embodiments, the number of the first electronic components E1 may be adjusted as needed. In one embodiment, after the step of disposing the first electronic component E1 on the peripheral circuit area R1 of the first substrate 13, it may optionally include the step of disposing a protective layer 61 (such as that shown in FIG. 3) on the first electronic component E1. The protective layer 61 may be used to increase the reliability of the first electronic component E1, reduce the peeling of the first electronic component E1, or block the entry of outside air or moisture to reduce the risk of panel deterioration.

In the present disclosure, as shown in FIG. 1C, the first electronic component E1 may include a chip on film (COF) or a flexible print circuit (FPC). The first electronic component E1 includes a flexible substrate (for example, the first flexible substrate E11) and a chip (for example, the first chip E12) disposed on the flexible substrate. The chip includes, for example, an integrated circuit (IC), but it is not limited thereto.

Then, as shown in FIG. 1D, the manufacturing method of an electronic device may further include: repeating the steps of FIG. 1A to FIG. 1C to form the second temporary panel 2′. The second temporary panel 2′ includes a third carrier board 21, a third substrate 23, a fourth substrate 24 and a fourth carrier board 22 arranged in sequence. Next, the second carrier board 12 and the third carrier board 21 are removed, and the second substrate 14 and the third substrate 23 are fixed with the attaching member AD1. In one embodiment of the present disclosure, the third substrate 23 has a peripheral circuit area R1. Before the step of removing the third carrier board 21, it may further include the step of disposing a second electronic component E2 in the peripheral circuit area R1 of the third substrate 23. Therefore, in one embodiment of the present disclosure, the second temporary panel 2′ may further include a second electronic component E2 disposed on the peripheral circuit area R1 of the third substrate 23. The second electronic component E2 is similar to the first electronic component E1 and thus will not be described again here. The number of second electronic components E2 may be the same as or different from the number of first electronic components E1. In summary, in the present disclosure, as shown in FIG. 1D, the manufacturing method of an electronic device may include the following steps: providing a first temporary panel 1′, wherein the first temporary panel 1′ includes a first carrier board 11, the first substrate 13, the second substrate 14 and the second carrier board 12 arranged in sequence; provide a second temporary panel 2′, wherein the second temporary panel 2′ includes the third carrier board 21, the third substrate 23, the fourth substrate 24 and the fourth carrier board 22 arranged in sequence; and removing the second carrier board 12 and the third carrier board 21, and fixing the second substrate 14 and the third substrate 23 with the attaching member AD1.

In the present disclosure, laser lift off (LLO) or non-laser lift off technology may be used to remove the second carrier board 12 and the third carrier board 21, but the present disclosure is not limited thereto. For example, the laser peeling technology may irradiate the surface of the second carrier board 12 away from the second substrate 14 with laser to form a peelable interface between the second carrier board 12 and the second substrate 14 so as to achieve the effect of separating the second carrier board 12 and the second substrate 14. The non-laser lift off technology may achieve the effect of separating the second carrier board 12 and the second substrate 14 by etching a lift-off layer (not shown) disposed between the second substrate 14 and the second carrier board 12, for example. However, the present disclosure is not limited thereto. In the present disclosure, the attaching member AD1 may include glass glue, optical glue, silicone glue, tape, hot melt glue, AB glue, two-component adhesive, polymer glue, or a combination thereof, but the present disclosure is not limited thereto. In one embodiment, the attaching member AD1 may be first disposed on the second substrate 14 through a lamination method, and then the second substrate 14 and the third substrate 23 are bonded together through a lamination method, but the present disclosure is not limited thereto. In another embodiment (not shown), the attaching member AD1 may also be disposed on the third substrate 23 by a lamination method, and then the third substrate 23 and the second substrate 14 are bonded together to achieve the purpose of fixing the second substrate 14 to the third substrate 23.

Next, as shown in FIG. 1E, when the electronic device includes three panels, the manufacturing method of an electronic device may further include: repeating the steps of FIG. 1A to FIG. 1C to form a third temporary panel 3′, wherein the third temporary panel 3′ includes a fifth carrier board 31, a fifth substrate 33, a sixth substrate 34 and a sixth carrier board 32 arranged in sequence. Then, similar to the steps shown in FIG. 1D, the fourth carrier board 22 and the fifth carrier board 31 are removed, and the fourth substrate 24 and the fifth substrate 33 are fixed with the attaching member AD2. In one embodiment, before the step of removing the fifth carrier board 31, it may further include the step of disposing a third electronic component E3 on the peripheral circuit area R1 of the fifth substrate 33. Therefore, in one embodiment, the third temporary panel 3′ may further include a third electronic component E3 disposed on the peripheral circuit area R1 of the fifth substrate 33.

In the present disclosure, the attaching member AD2 is similar to the attaching member AD1, such as similar material or thickness, and the third electronic component E3 is similar to the first electronic component E1 or the second electronic component E2, and thus a detailed description is deemed unnecessary. In addition, the method of removing the fourth carrier board 22 and the fifth carrier board 31 and the method of installing the attaching member AD2 may also be as described above, and thus will not be described again here. In some embodiments, in the normal direction Z (top view direction) of the electronic device, the first electronic component E1, the second electronic component E2 and/or the third electronic component E3 may, for example, overlap each other, and the above overlapping may include at least partial overlapping or complete overlapping. In some embodiments, in the normal direction Z (top view direction) of the electronic device, the attaching member AD1 and the attaching member AD2 overlap each other, for example. In some embodiments, the attaching member AD1 and the attaching member AD2 may respectively include filter particles of different colors, but the present disclosure is not limited thereto.

Then, as shown in FIG. 1F, the manufacturing method of an electronic device may further include: removing the sixth carrier board 32 and fixing the protective substrate 4 and the sixth substrate 34 with the attaching member AD3, wherein the attaching member AD3 is similar to the attaching member AD1 and thus a detailed description is deemed unnecessary. In addition, the method of removing the sixth carrier board 32 and the method of disposing the attaching member AD3 may also be as described above, and thus will not be described again here.

Next, as shown in FIG. 1G, the manufacturing method of an electronic device may further include: removing the first carrier board 11, and disposing the first panel 13 on a supporting component 5, thereby completing the electronic device of one embodiment of the present disclosure. In other words, the supporting component 5 is arranged under the first panel 13. In some embodiments, the supporting component 5 overlaps the display area R2 (refer to the following FIG. 3) and at least a portion of the peripheral circuit area R1 (refer to the following FIG. 3) of the first substrate 13 of the first panel 13, and the thickness of the supporting component 5 is greater than the thickness of the first substrate 13, while the details will be explained in FIG. 3. Here, the method of removing the first carrier board 11 may be as described above and thus will not be described again here. In some embodiments, the area of the supporting component 5 is, for example, smaller than or equal to the area of the first substrate 13 of the first panel 1 (as shown in FIG. 3). In some embodiments, the width of the supporting component 5 in the X direction is, for example, smaller than or equal to the width of the first substrate 13 of the first panel 1 (as shown in FIG. 3) in the X direction. In some embodiments (not shown), the width of the supporting component 5 in the Y direction is, for example, smaller than or equal to the width of the first substrate 13 of the first panel 1 (as shown in FIG. 3) in the Y direction. In some embodiments (not shown), the area of the supporting component 5 is, for example, greater than or equal to the area of the first substrate 13 of the first panel 1 (as shown in FIG. 3). In some embodiments, the width of the supporting component 5 in the X direction is, for example, greater than or equal to the width of the first substrate 13 of the first panel 1 (as shown in FIG. 3) in the X direction. In some embodiments (not shown), the width of the supporting component 5 in the Y direction is, for example, greater than or equal to the width of the first substrate 13 of the first panel 1 (as shown in FIG. 3) in the Y direction.

In some embodiments, the material of the supporting component 5 may include polycarbonate (PC), polyimide (PI), polypropylene (PP), polyethylene terephthalate (PET), polymethylmethacrylate (PMMA), other suitable materials or a combination thereof, but the present disclosure is not limited thereto. In one embodiment, the supporting component 5 may include a light-shielding substrate or the supporting component 5 may include a light-shielding material, such as black organic material, black inorganic material, black ink, black tape, other suitable materials or a combination thereof, but the present disclosure is not limited thereto. When the supporting component 5 includes a light-shielding material, its transmittance may be, for example, smaller than 50%, or smaller than 70%, or even smaller than 80%.

In one embodiment of the present disclosure, as shown in FIG. IF and FIG. 1G, the protective substrate 4 is first provided and then the supporting component 5 is provided, but the present disclosure is not limited thereto. The order of providing the supporting component 5 and the protective substrate 4 may be adjusted according to the actual needs.

In the present disclosure, the electronic device shown in FIG. 3 to FIG. 7, for example, may be obtained through the above manufacturing method, which may make the electronic device flexible or achieve the purpose of thinning the electronic device.

FIG. 2A and FIG. 2B are respectively enlarged views of a portion of FIG. 1B-2. In more detail, FIG. 2A and FIG. 2B are respectively enlarged views at the dotted box of FIG. 1B-2, wherein some components are omitted from the schematic diagram for convenience of explanation.

In one embodiment of the present disclosure, when the electronic device is manufactured by the steps shown in FIG. 1B-2, the pre-cutting step of the first mother substrate 13′ and the second mother substrate 14′ may be omitted and, in the subsequent cutting step, in order to reduce damage to the circuit layer (not shown) or components on the first mother substrate 13′ and/or the second mother substrate 14′, in one embodiment, as shown in FIG. 2A and FIG. 2B, a protective element P1 may be disposed at a position corresponding to the cutting line (for example, the dotted line in FIG. 1B-2 or the arrow in FIG. 2A and FIG. 2B), and the protective element P1 is, for example, disposed in the first mother substrate 13′ to reduce the risk of damage to the circuit layer (not shown) or components on the first mother substrate 13′ during the cutting step.

More specifically, in one embodiment, as shown in FIG. 2A, the first mother substrate 13′ may include a substrate 13′-1; a conductive layer 13′-2 (which may be equivalent to a portion of the circuit layer) disposed on the substrate 13′-1; a protective clement Pl disposed on the conductive layer 13′-2, and disposed roughly corresponding to the position of the cutting line; and an insulating layer 13′-3 disposed on the conductive layer 13′-2 and the protective element P1. The protective element P1 may contact the conductive layer 13′-2, for example, but the present disclosure is not limited thereto. In the normal direction Z (top view direction) of the electronic device, the thickness (not labeled) of the protective element P1 is, for example, smaller than the thickness (not labeled) of the insulating layer 13′-3 that covers the protective element P1, for example. In one embodiment, the second mother substrate 14′ is disposed corresponding to the first mother substrate 13′. The components on the second mother substrate 14′ are omitted here. The second mother substrate 14′ may be similar to the first mother substrate 13′ and include components such as a conductive layer (not shown) and an insulating layer (not shown), and thus a detailed description is deemed unnecessary.

In another implementation aspect, as shown in FIG. 2B, the first mother substrate 13′ may include a substrate 13′-1; a conductive layer 13′-2 disposed on the substrate 13′-1; and an insulating layer 13′-3 disposed on the conductive layer 13′-2; and a protective clement P1. In one embodiment, the second mother substrate 14′ is disposed corresponding to the first mother substrate 13′. The protective element P1 is not in contact with the conductive layer 13′-2, for example. The protective element P1 is, for example, adjacent to or in contact with the second mother substrate 14′, but the present disclosure is not limited thereto. In the normal direction Z (top view direction) of the electronic device, the thickness (not labeled) of the protective element P1 is, for example, smaller than the thickness (not labeled) of the insulating layer 13′-3. The components on the second mother substrate 14′ are omitted here. The second mother substrate 14′ may be similar to the first mother substrate 13′ and include components such as a conductive layer (not shown) and an insulating layer (not shown), which will not be repeated here. In the present disclosure, the material of the protective element P1 includes, for example, metal material or light-shielding material. The metal material includes, for example, silver, copper, other suitable materials, or a combination thereof, but the present disclosure is not limited thereto. The Light-shielding material includes (black) photoresist, black insulating materials (such as organic material or inorganic material), etc.

FIG. 3 is a schematic cross-sectional view of an electronic device according to an embodiment of the present disclosure.

In one embodiment, as shown in FIG. 3, the electronic device may include: a supporting component 5; a first panel 1 disposed on the supporting component 5; a second panel 2 disposed on the first panel 1; a third panels 3 disposed on the second panel 2; and a protective substrate 4 disposed on the third panel 3. In more detail, the first panel 1 includes: a first substrate 13 having a display area R2 and a peripheral circuit area R1; a second substrate 14 disposed on the first substrate 13; and a first display layer 15 disposed on the first substrate 13 and the second substrate 14. The supporting component 5 overlaps the display area R2 and at least part of the peripheral circuit area R1 of the first substrate 13, and the thickness T4 of the supporting component 5 is greater than the thickness T5 of the first substrate 13. The second panel 2 includes: a third substrate 23 having a display area R2 and a peripheral circuit area R1; a fourth substrate 24 disposed on the third substrate 23; and a second display layer 25 disposed between the third substrate 23 and the fourth substrate 24, wherein the supporting component 5 overlaps the display area R2 and at least part of the peripheral circuit area R1 of the third substrate 23, and the thickness T4 of the supporting component 5 is greater than the thickness of the third substrate 23 (not labeled). The third panel 3 includes: a fifth substrate 33 having a display area R2 and a peripheral circuit area R1; a sixth substrate 34 disposed on the fifth substrate 33; and a third display layer 35 disposed between the fifth substrate 33 and the sixth substrate 34, wherein the supporting component 5 overlaps the display area R2 and at least part of the peripheral circuit area R1 of the fifth substrate 33, and the thickness T5 of the supporting component 5 is greater than the thickness of the fifth substrate 33 (not labeled). In the present disclosure, as shown in FIG. 3, in the normal direction Z (top view direction) of the electronic device, the display area R2 of the first substrate 13 substantially overlaps the display area R2 of the third substrate 23, and the display area R2 of the third substrate 23 substantially overlaps the display area R2 of the fifth substrate 33. As shown in FIG. 3, in the normal direction Z (top view direction) of the electronic device, the peripheral circuit area R1 of the first substrate 13 substantially overlaps the peripheral circuit area R1 of the third substrate 23, and the peripheral circuit area R1 of the third substrate 23 substantially overlaps the peripheral circuit area R1 of the fifth substrate 33. The protective substrate 4 may be provided with a light-shielding pattern 41. In the normal direction Z (top view direction) of the electronic device, the light-shielding pattern 41 overlaps the peripheral circuit area R1 of the first substrate 13, the peripheral circuit area R1 of the third substrate 23 and/or the peripheral circuit area R1 of the fifth substrate 33. By overlapping the supporting component 5 with the display area R2 and at least part of the peripheral circuit area R1 of the first substrate 13, the reliability of the electronic device can be improved.

In the present disclosure, the material of the supporting component 5 is as mentioned above and thus will not be described again. In the present disclosure, the thickness T5 of the supporting component 5 may be 50 micrometers (μm) to 200 micrometers (μm) (50 μm≤T5≤200 μm), such as 80 micrometers (μm) to 150 micrometers (μm) (80 μm≤T5≤150 μm), 80 micrometers (μm) to 120 micrometers (μm) (80 μm≤T5≤120 μm), etc., but the present disclosure is not limited thereto. When the thickness T5 of the supporting component 5 is greater than the thickness T4 of the first substrate 13, the reliability of the electronic device can be improved. In one embodiment, the ratio of the thickness T5 of the supporting component 5 to the thickness T4 of the first substrate 13 may be greater than or equal to 3 and smaller than or equal to 15. In one embodiment, the ratio of the thickness T5 of the supporting component 5 to the thickness T4 of the first substrate 13 may be greater than or equal to 3 and smaller than or equal to 10. In one embodiment, the ratio of the thickness T5 of the supporting component 5 to the thickness T4 of the first substrate 13 may be greater than or equal to 3 and smaller than or equal to 8. In one embodiment, the ratio of the thickness T5 of the supporting component 5 to the thickness T4 of the first substrate 13 may be greater than or equal to 3 and smaller than or equal to 5. When the ratio of the thickness T5 of the supporting component 5 to the thickness T4 of the first substrate 13 meets the above relationship, the supportability of the supporting component 5 can be maintained while taking into account the overall thickness of the electronic device.

In the present disclosure, the thickness T5 of the supporting component 5 is, for example, smaller than or equal to the thickness (not labeled) of the protective substrate 4. In the present disclosure, the width (not labeled) of the supporting component 5 in the X direction is, for example, smaller than or equal to the width (not labeled) of the protective substrate 4 in the X direction. In the present disclosure, the width (not labeled) of the supporting component 5 in the Y direction is, for example, smaller than or equal to the width (not labeled) of the protective substrate 4 in the Y direction.

In one embodiment, the materials of the first substrate 13, the second substrate 14, the third substrate 23, the fourth substrate 24, the fifth substrate 33 and the sixth substrate 34 may each include polycarbonate (PC), polyimide (PI), polypropylene (PP), polyethylene terephthalate (PET), polymethylmethacrylate (PMMA), and other suitable materials or a combination thereof, but the present disclosure is not limited thereto. The materials of the first substrate 13, the second substrate 14, the third substrate 23, the fourth substrate 24, the fifth substrate 33 and the sixth substrate 34 may be the same or different. The thickness of the first substrate 13, the second substrate 14, the third substrate 23, the fourth substrate 24, the fifth substrate 33 and the sixth substrate 34 may each be 10 micrometers (μm) to 50 micrometers (μm) (10 μm≤thickness≤50 μm), but the present disclosure is not limited thereto. The thickness of the first substrate 13, the second substrate 14, the third substrate 23, the fourth substrate 24, the fifth substrate 33 and the sixth substrate 34 may each be 15 micrometers (μm) to 40 micrometers (μm) (15 μm≤thickness≤40 μm). The thickness of the first substrate 13, the second substrate 14, the third substrate 23, the fourth substrate 24, the fifth substrate 33 and the sixth substrate 34 may each be 20 micrometers (μm) to 30 micrometers (μm) (20 μm≤thickness≤30 μm). The thickness of the first substrate 13, the second substrate 14, the third substrate 23, the fourth substrate 24, the fifth substrate 33 and the sixth substrate 34 may each be 10 micrometers (μm) to 20 micrometers (μm) (10 μm≤thickness≤20 μm). In one embodiment, the material of the protective substrate 4 may include quartz, glass, wafer, sapphire, ceramic material, polycarbonate (PC), polyimide (PI), polypropylene (PP), polyethylene terephthalate (PET) or other plastic materials, but the present disclosure is not limited thereto. In one embodiment, the material of the light-shielding pattern 41 may include light-shielding (black) organic material, light-shielding (black) inorganic material, light-shielding (black) ink, light-shielding (black) tape, other suitable materials or a combination thereof, but the present disclosure is not limited thereto. The light-shielding pattern 41 may be formed, for example, by spraying, screen printing or other suitable methods. In one embodiment, in the normal direction Z (top view direction) of the electronic device, the light-shielding pattern 41 may, for example, overlap the peripheral circuit area R1. In one embodiment, in the normal direction Z (top view direction) of the electronic device, the light-shielding pattern 41 may, for example, overlap a portion of the display area R2.

In the present disclosure, the first display layer 15, the second display layer 25 and the third display layer 35 may each include a guest host type liquid crystal (GHLC), a dye liquid crystal, or a twisted nematic liquid crystal (TN LC), super twisted nematic liquid crystal (STN LC), polymer dispersed liquid crystal (PDLC), polymer network liquid crystal (PNLC), cholesteric texture liquid crystal, polymer-stabilized cholesteric texture liquid crystal (PSCT LC), suspended particle material (SPD), electrochromic material, etc., or a combination thereof, but the present disclosure is not limited thereto. In one embodiment of the present disclosure, the first display layer 15, the second display layer 25 and the third display layer 35 may each include the cholesteric liquid crystal. For example, the first display layer 15 includes the cholesteric liquid crystal that reflects red light, the second display layer 15 includes the cholesteric liquid crystal that reflects green light 25, and the third display layer 35 includes the cholesteric liquid crystal that reflects blue light. However, the present disclosure is not limited thereto. The above display layers may selectively reflect light of different colors. When the first display layer 15, the second display layer 25 and the third display layer 35 comply with the above design, the reflection efficiency of incident light can be improved, thereby improving the display quality of the electronic device.

In one embodiment of the present disclosure, as shown in FIG. 3, the electronic device may further include a sealant S1, a sealant S2 and a sealant S3. The sealant S1 is disposed between the first substrate 13 and the second substrate 14 and surrounds the first display layer 15. The sealant S2 is disposed between the third substrate 23 and the fourth substrate 24 and surrounds the second display layer 25. The sealant S3 is disposed between the fifth substrate 33 and the sixth substrate 34 and surrounds the third display layer 35. In one embodiment of the present disclosure, as shown in FIG. 3, the electronic device may further include an attaching member AD1, an attaching member AD2 and an attaching member AD3. The attaching member AD1 is disposed between the first panel 1 and the second panel 2. The attaching member AD2 is disposed between the second panel 2 and the third panel 3, and the attaching member AD3 is disposed between the third panel 3 and the protective substrate 4, but it is not limited thereto. In one embodiment, in the normal direction Z (top view direction) of the electronic device, the light-shielding pattern 41 may overlap the sealant S1, the sealant S2 and/or the sealant S3, for example.

In the present disclosure, the attaching members AD1, AD2 and AD3 may each include glass glue, optical glue, silicone glue, tape, hot melt glue, AB glue, two-component adhesive, polymer glue material or a combination thereof, but the present disclosure is not limited thereto. The thicknesses of the attaching members AD1, AD2 and AD3 may each be 50 micrometers (μm) to 1000 micrometers (μm) (50 μm≤thickness≤1000 μm), but the present disclosure is not limited thereto. The thicknesses of the attaching members AD1, AD2 and AD3 may each be 50 micrometers (μm) to 500 micrometers (μm) (50 μm≤thickness≤500 μm), but the present disclosure is not limited thereto. The thicknesses of the attaching members AD1, AD2 and AD3 may each be 50 micrometers (μm) to 350 micrometers (μm) (50 μm≤thickness≤350 μm), but the present disclosure is not limited thereto. The thicknesses of the attaching members AD1, AD2 and AD3 may each be 150 micrometers (μm) to 250 micrometers (μm) (150 μm≤thickness≤250 μm), but the present disclosure is not limited thereto. The thicknesses of the attaching members AD1, AD2 and AD3 may each be 170 micrometers (μm) to 230 micrometers (μm) (170 μm≤thickness≤230 μm), but the present disclosure is not limited thereto. In some embodiments, the thickness T7 of the attaching member AD3 may be greater than or equal to the thickness of the attaching member AD1 or AD2. In some embodiments, the ratio of the thickness T6 of the light-shielding pattern 41 to the thickness T7 of the attaching member AD3 may be between 0.003 and 0.6, but it is not limited thereto. In some embodiments, the ratio of the thickness T6 of the light-shielding pattern 41 to the thickness T7 of the attaching member AD3 may be between 0.005 and 0.4, but it is not limited thereto. In some embodiments, the ratio of the thickness T6 of the light-shielding pattern 41 to the thickness T7 of the attaching member AD3 may be between 0.008 and 0.3, but it is not limited thereto. In some embodiments, the ratio of the thickness T6 of the light-shielding pattern 41 to the thickness T7 of the attaching member AD3 may be between 0.01 and 0.2, but it is not limited thereto. In some embodiments, the ratio of the thickness T6 of the light-shielding pattern 41 to the thickness T7 of the attaching member AD3 may be between 0.01 and 0.1, but it is not limited thereto. In some embodiments, the ratio of the thickness T6 of the light-shielding pattern 41 to the thickness T7 of the attaching member AD3 may be between 0.015 and 0.1, but it is not limited thereto.

In one embodiment of the present disclosure, as shown in FIG. 3, the electronic device may further include: a first electronic component E1 disposed on the peripheral circuit area R1 of the first substrate 13; a second electronic component E2 disposed on the peripheral circuit area R1 of the third substrate 23; and a third electronic component E3 disposed on the peripheral circuit area R1 of the fifth substrate 33. In one embodiment, in the normal direction Z (top view direction) of the electronic device, the first electronic component E1 may overlap the second electronic component E2, and the second electronic component E2 (or the first electronic component E1) may overlap the third electronic component E3, but the present disclosure is not limited thereto. In one embodiment, in the normal direction Z (top view direction) of the electronic device, the light-shielding pattern 41 may overlap the first electronic component E1, the second electronic component E2, and/or the third electronic component E3, for example.

In the present disclosure, the first electronic component E1, the second electronic component E2 and the third electronic component E3 may each include a chip on film (COF) or a flexible print circuit (FPC), but the present disclosure is not limited thereto. The chip on film includes a flexible substrate (such as the first flexible substrate E11, the second flexible substrate E21, and the third flexible substrate E31) and a chip (such as the first chip E12, the second chip E22 and the third chip E32) disposed on the flexible substrate. The chip may be, for example, an integrated circuit (IC). In one embodiment of the present disclosure, the first electronic component E1, the second electronic component E2 and the third electronic component E3 may each be a chip on film. Therefore, the first electronic component E1 may include: the first flexible substrate E11; and the first chip E12 disposed on the first flexible substrate E11. The second electronic component E2 may include: a second flexible substrate E21; and a second chip E22 disposed on the second flexible substrate E21. The third electronic component E3 may include: a third flexible substrate E31; and a third chip E32 disposed on the third flexible substrate E31. In some embodiments, the thickness of the first flexible substrate E11, the second flexible substrate E21, and the third flexible substrate E31 may each be 20 micrometers (μm) to 100 micrometers (μm) (20 μm≤thickness≤100 μm). In some embodiments, the thickness of the first flexible substrate E11, the second flexible substrate E21, and the third flexible substrate E31 may each be 30 micrometers (μm) to 80 micrometers (μm) (30 μm≤thickness≤80 μm). In some embodiments, the thickness of the first flexible substrate E11, the second flexible substrate E21, and the third flexible substrate E31 may each be 40 micrometers (μm) to 70 micrometers (μm) (40 μm≤thickness≤70 μm). In some embodiments, the thickness of the first flexible substrate E11, the second flexible substrate E21, and the third flexible substrate E31 may each be 45 micrometers (μm) to 65 micrometers (μm) (45 μm≤thickness≤65 μm).

In the present disclosure, as shown in FIG. 3, the attaching member AD1 has a first thickness T1, the second substrate 14 has a second thickness T2, and the first flexible substrate E11 of the first electronic component E1 has a third thickness T3, wherein the first thickness T1, the second thickness T2 and the third thickness T3 may satisfy the following equation (1): 1.5≤(T1+T2)/T3≤7.5.

When the thickness relationship of the above components complies with the equation (1), damage to the electronic device can be reduced or the electronic device can be made thinner. More specifically, when the thickness relationship of the above components is greater than or equal to 1.5 (that is, (T1+T2)/T3≥1.5), it is able to reduce the collision or extrusion of the first electronic component E1 with the third substrate 23 of the second panel 2 or with the second electronic component E2, so as to improve the yield rate of the electronic device. If the thickness relationship of the above components is greater than 7.5 (that is, (T1+T2)/T3>7.5), the overall thickness of the electronic device will increase, which is not conducive to thin design. In other embodiments of the present disclosure, the thickness relationship of the attaching member AD2, the fourth substrate 24 and the second flexible substrate E21 of the second electronic component E2 is also the same as the thickness relationship of the attaching member AD1, the second substrate 14 and the first flexible substrate E11 of the first electronic component E1, and thus a detailed description is deemed unnecessary.

In one embodiment of the present disclosure, as shown in FIG. 3, in the direction perpendicular to the normal direction Z of the electronic device (for example, the X direction), the first chip E12 is separated from the third substrate 23 of the second panel 2 by a distance D, which can reduce collision or extrusion between the first electronic component E1 and the third substrate 23 of the second panel 2, thereby improving the yield of the electronic device, but it is not limited thereto. In other embodiments of the present disclosure, in the direction perpendicular to the normal direction Z of the electronic device (for example, the X direction), the second chip E22 may be separated from the fifth substrate 33 of the third panel 3 by another distance (not marked), which will not be described again here.

In one embodiment, as shown in FIG. 3, the first electronic component E1 is disposed on the peripheral circuit area R1 of the first substrate 13. The electronic device may include a protective layer 61 disposed between the second panel 2 and the first electronic component E1. More specifically, the protective layer 61 is disposed between the second panel 2 and the first flexible substrate E11 of the first electronic component E1. The protective layer 61 may at least cover a side wall E111 of the first flexible substrate E11. The protective layer 61 contacts part of the flexible substrate E11. The protective layer 61 may be used to increase the reliability of the first electronic component E1 and reduce peeling of the first electronic component E1. In addition, as shown in FIG. 3, the protective layer 61 may be in contact with the side wall 141 of the second substrate 14, which may reduce the entry of outside air or moisture and reduce the risk of deterioration of the first panel 1. Similarly, the electronic device may further include a protective layer 62 and a protective layer 63. The protective layer 62 and the protective layer 63 may be designed similar to the protective layer 61, thereby increasing the reliability of the electronic device or reducing the risk of deterioration, which will not be described again here. n the present disclosure, the materials of the protective layer 61, the protective layer 62 and the protective layer 63 may each include glass glue, optical glue, silicone glue, tape, hot melt glue, AB glue, two-component adhesive, light-curing glue, polymer glue, resin or a combination thereof, but the present disclosure is not limited thereto.

In one embodiment of the present disclosure, as shown in FIG. 3, the electronic device may not include a backlight module, and may use the display layer (such as the first display layer 15, the second display layer 25, and the third display layer 35) for reflection to thus emit reflected lights of different colors (as shown by the arrows in FIG. 3) thereby achieving the purpose of image display, so as to enable the electronic device to save power or become thinner and light-weight.

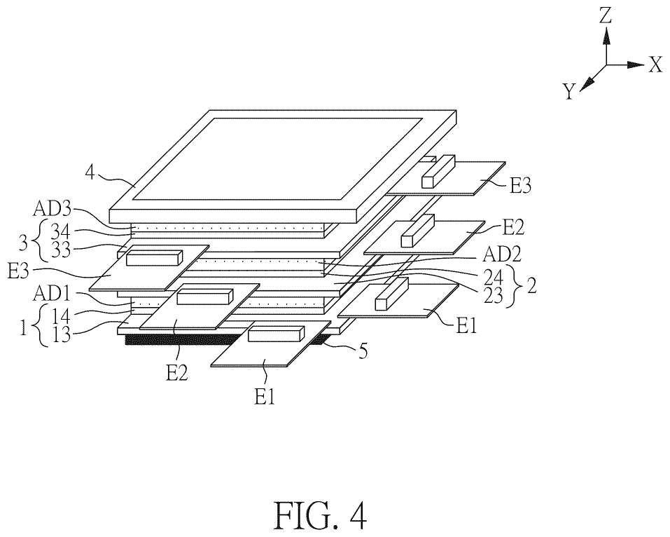

FIG. 4 is a schematic three-dimensional view of an electronic device according to an embodiment of the present disclosure. The electronic device of FIG. 4 may be manufactured using the manufacturing method of FIG. 1A to FIG. 1G, and the electronic device of FIG. 4 is similar to the electronic devices shown in FIG. 1G and FIG. 3, except for the following differences.

In one embodiment of the present disclosure, as shown in FIG. 4, the first electronic component E1, the second electronic component E2 and the third electronic component E3 may be disposed in a staggered manner. More specifically, in the normal direction (top view direction) of the electronic device, the first electronic component E1 and the second electronic component E2 do not overlap, and the second electronic component E2 and the third electronic component E3 do not overlap. In this way, the collision or extrusion of the first electronic component E1 and the second electronic component E2 may be reduced, or the collision or extrusion of the second electronic component E2 and the third electronic component E3 may be reduced, thereby improving the yield rate of the electronic device. In other embodiments (not shown), in the normal direction Z (top view direction) of the electronic device, at least two of the first electronic component E1, the second electronic component E2 and the third electronic component E3 may partially overlap or may not overlap with each other. In other embodiments (not shown), in the normal direction Z (top view direction) of the electronic device, the chips respectively included in the first electronic component E1, the second electronic component E2 and the third electronic component E3 may not overlap with each other.

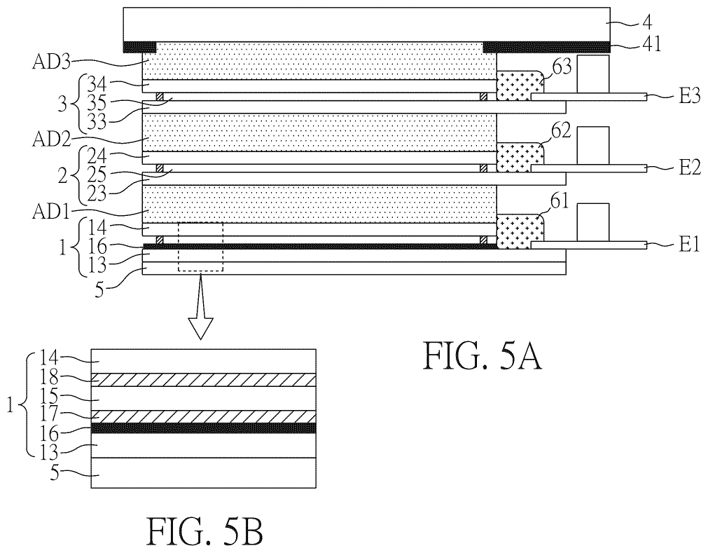

FIG. 5A is a schematic cross-sectional view of an electronic device according to an embodiment of the present disclosure, and FIG. 5B is an enlarged view of a portion of FIG. 5A, wherein the electronic device of FIG. 5A is similar to the electronic device of FIG. 3 except for the following differences.

In one embodiment, the supporting component 5 may not include a light-shielding material, the electronic device may include a light-shielding layer 16, and the light-shielding layer 16 may be disposed on the first substrate 13. More specifically, as shown in FIG. 5A and FIG. 5B, the first panel 1 may include a first substrate 13; a second substrate 14 disposed on the first substrate 13; a light-shielding layer 16 disposed on the first substrate 13; a conductive layer 17 disposed on the light-shielding layer 16; a conductive layer 18 disposed between the second substrate 14 and the first substrate 13; and a first display layer 15 disposed between the conductive layer 17 and the conductive layer 18. The light-shielding layer 16 may be used to absorb light so as to improve the display quality of the electronic device.

In the present disclosure, the material of the light-shielding layer 16 may include, for example, black organic material, black inorganic material, black ink, other suitable materials, or a combination thereof, but the present disclosure is not limited thereto. In the present disclosure, the materials of the conductive layer 17 and the conductive layer 18 may each include a transparent conductive material, such as indium zinc oxide (IZO), indium tin oxide (ITO), indium tin zinc oxide (ITZO), indium gallium zinc oxide (IGZO), aluminum zinc oxide (AZO), or a combination thereof, but the present disclosure is not limited thereto. In the present disclosure, a suitable coating method may be used to provide the light-shielding layer 16. The suitable coating method may be, for example, spray coating, spin coating, or evaporation, but the present disclosure is not limited thereto.

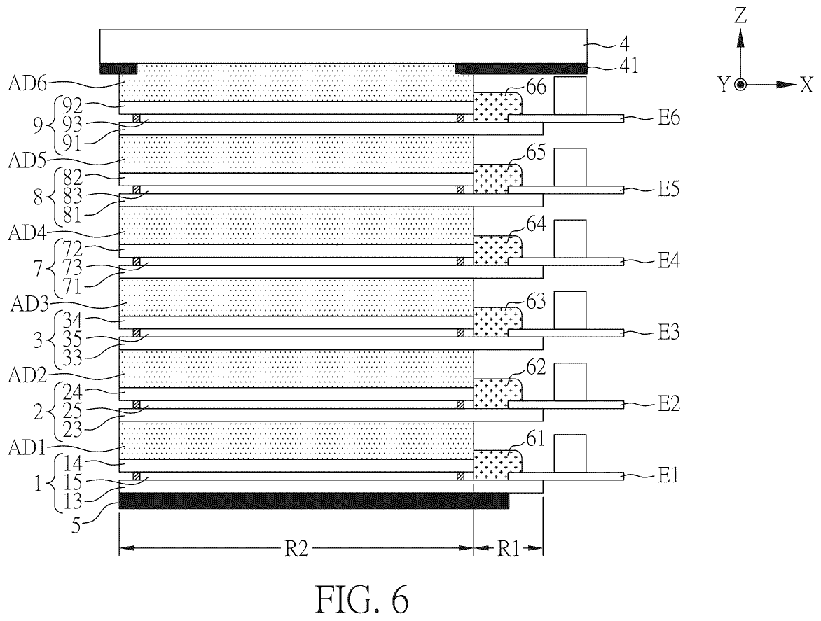

FIG. 6 is a schematic cross-sectional view of an electronic device according to an embodiment of the present disclosure. The electronic device of FIG. 6 is similar to the electronic device of FIG. 3 except for the following differences.

In one embodiment, as shown in FIG. 6, the electronic device may further include: a fourth panel 7 disposed between the third panel 3 and the protective substrate 4; a fifth panel 8 disposed between the fourth panel 7 and the protective substrate 4; a sixth panel 9 disposed between the fifth panel 8 and the protective substrate 4. There are an attaching member AD4, an attaching member AD5, and an attaching member AD6 respectively included between each panel (for example, the fourth panel 7, the fifth panel 8, and the sixth panel 9) and the protective substrate 4. For example, the attaching member AD4 is disposed between the fourth panel 7 and the fifth panel 8, the attaching member AD5 is disposed between the fifth panel 8 and the sixth panel 9, and the attaching member AD6 is disposed between the sixth panel 9 and the protective substrate 4, thereby fixing the panels to each other.

In one embodiment, as shown in FIG. 6, the electronic device may further include: a protective layer 64, which is disposed between the fifth panel 8 and the electronic component E4 for increasing the reliability of the electronic component E4, reducing the risk of the peeling of the electronic component E4 or reducing the entry of outside air or moisture to thus reduce the risk of deterioration of the fourth panel 7. In addition, the electronic device may further include a protective layer 65 and an attaching member 66. The protective layer 65 and the attaching member 66 may be designed similar to the protective layer 64 thereby increasing the reliability of the electronic device or reducing the risk of deterioration, which will not be described in detail here.

In one embodiment, the fourth panel 7 includes: a substrate 71 having a display area R2 and a peripheral circuit area R1; an opposite side substrate 72 disposed corresponding to the substrate 71; and a fourth display layer 73 arranged between the substrate 71 and the opposite side substrate 72; and an electronic component E4 disposed on the peripheral circuit area R1 of the substrate 71. The fifth panel 8 includes: a substrate 81 having a display area R2 and a peripheral circuit area R1; an opposite side substrate 82 disposed corresponding to the substrate 81; a fifth display layer 83 disposed between the substrate 81 and the opposite side substrate 82; and an electronic component E5 disposed on the peripheral circuit area R1 of the substrate 81. The sixth panel 9 includes: a substrate 91 having a display area R2 and a peripheral circuit area R1; an opposite side substrate 92 disposed corresponding to the substrate 91; a sixth display layer 93 disposed between the substrate 91 and the opposite side substrate 92; and an electronic component E6 disposed on the peripheral circuit area R1 of the substrate 91.

In the present disclosure, the materials of the substrate 71, the substrate 81, the substrate 91, the opposite side substrate 72, the opposite side substrate 82 and the opposite side substrate 92 may each be similar to that of the first substrate 13. The electronic component E4, the electronic component E5 and the electronic component E6 may each be similar to the first electronic component E1. The materials of the protective layer 64, the protective layer 65 and the protective layer 66 may each be similar to that of the protective layer 61, and thus a detailed description is deemed unnecessary.

In one embodiment, as shown in FIG. 6, the first display layer 15, the second display layer 25, the third display layer 35, the fourth display layer 73, the fifth display layer 83 and the sixth display layer 93 may each include cholesteric liquid crystal. For example, the first display layer 15 and the second display layer 25 may each be cholesteric liquid crystal that reflects red light, the third display layer 35 and the fourth display layer 73 may each be cholesteric liquid crystal that reflects green light, and the fifth display layer 83 and the sixth display layer 93 may each be cholesteric liquid crystal that reflects blue light, wherein the first display layer 15 and the second display layer 25 have different optical rotations (for example, one is left-handed and the other one is right-handed), the third display layer 35 and the fourth display layer 73 have different optical rotations (for example, one is left-handed and the other one is right-handed), and the fifth display layer 83 and the sixth display layer 93 have different optical rotations (for example, one is left-handed and the other is right-handed), but the present disclosure is not limited thereto. When the first display layer 15, the second display layer 25, the third display layer 35, the fourth display layer 73, the fifth display layer 83 and the sixth display layer 93 comply with the above design, the reflection efficiency of the incident light can be increased, thereby improving the display quality of the electronic device. In other embodiments (not shown), part of the aforementioned panels may be removed as needed.

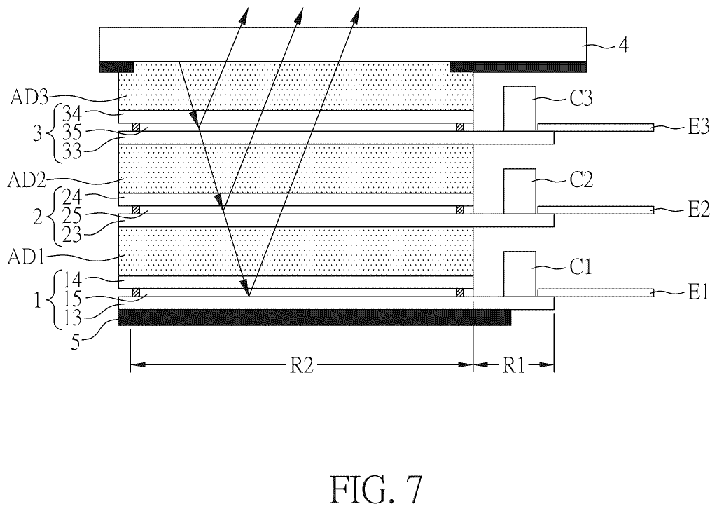

FIG. 7 is a schematic cross-sectional view of an electronic device according to an embodiment of the present disclosure. The electronic device of FIG. 7 is similar to the electronic device of FIG. 3 except for the following differences.

In one embodiment of the present disclosure, as shown in FIG. 7, the first electronic component E1, the second electronic component E2 and the third electronic component E3 of the electronic device are each a flexible circuit board, and are respectively disposed on the peripheral circuit areas R1 of the first substrate 13, the third substrate 23 and the fifth substrate 33. In addition, the first panel 1 further includes a chip C1 disposed on the peripheral circuit area R1 of the first substrate 13, the second panel 2 further includes a chip C2 disposed on the peripheral circuit area R1 of the third substrate 23, and the third panel 3 further includes a chip C3 disposed on the peripheral circuit area R1 of the fifth substrate 33. In one embodiment of the present disclosure, in the normal direction Z (top view direction) of the electronic device, the chip C1 and the third substrate 23 of the second panel 2 are, for example, separated by a distance (not labeled); that is, the chip C1 is not in contact with the third substrate 23 of the second panel 2, for example. Similarly, in the normal direction Z (top view direction) of the electronic device, the chip C2 and the fifth substrate 33 of the third panel 3 are, for example, separated by a distance (not labeled); that is, the chip C2 is not in contact with the fifth substrate 33 of the third panel 3, for example. In the present disclosure, the electronic device may include a display device, an antenna device, a sensing device or a tiled device, but the present disclosure is not limited thereto. The electronic device may be a bendable or flexible electronic device. The display device may be a non-self-luminous display device. The antenna device may be a liquid crystal antenna device. The sensing device may be a sensing device that senses capacitance, light, thermal energy or ultrasonic waves, but the present disclosure is not limited thereto. The tiled device may be, for example, a display tiled device or an antenna tiled device, but the present disclosure is not limited thereto. In the present disclosure, the electronic device may be applied to electronic devices that do not require a backlight module, such as displays, music players, e-books, writing tablets, or billboards, but the present disclosure is not limited thereto.

The aforementioned specific embodiments should be construed as merely illustrative, and not limiting the rest of the present disclosure in any way.

1. A manufacturing method of an electronic device, comprising the steps of:
providing a first temporary panel, wherein the first temporary panel includes a first carrier board, a first substrate, a second substrate and a second carrier board arranged in sequence;
providing a second temporary panel, wherein the second temporary panel includes a third carrier board, a third substrate, a fourth substrate and a fourth carrier board arranged in sequence; and
removing the second carrier board and the third carrier board, and fixing the second substrate and the third substrate with an attaching member.

2. The manufacturing method as claimed in claim 1, wherein the first substrate has a first peripheral circuit area and, before the step of removing the second carrier board, the manufacturing method further comprises the step of disposing a first electronic component on the first peripheral circuit area.

3. The manufacturing method as claimed in claim 2, wherein the first electronic component includes a chip on film or a flexible circuit board.

4. The manufacturing method as claimed in claim 3, wherein the attaching member has a first thickness, the second substrate has a second thickness, the first electronic component includes a flexible substrate, and the flexible substrate has a third thickness, where the first thickness, the second thickness and the third thickness satisfy:
$$1.5 ≦ ( T 1 + T 2 ) / T 3 ≦ 7.5 ,$$
where T1 represents the first thickness, T2 represents the second thickness, and T3 represents the third thickness.

5. The manufacturing method as claimed in claim 1, wherein the third substrate has a second peripheral circuit area and, before the step of removing the third carrier board, the manufacturing method further comprises the step of disposing a second electronic component on the second peripheral circuit area.

6. The manufacturing method as claimed in claim 1, further comprising the step of:
removing the first carrier board, and disposing the first panel on a supporting component, wherein the supporting component has a thickness greater than that of the first substrate.

7. The manufacturing method as claimed in claim 6, wherein the first substrate further has a display area, and the supporting component overlap the display area of the first substrate and at least a portion of the peripheral circuit area.

8. The manufacturing method as claimed in claim 1, further comprising the steps of:
providing a third temporary panel, wherein the third temporary panel includes a fifth carrier board, a fifth substrate, a sixth substrate and a sixth carrier board; and
removing the fourth carrier board and the fifth carrier board, and fixing the fourth substrate and the fifth substrate with an attaching member.

9. The manufacturing method as claimed in claim 8, further comprising the step of:
removing the sixth carrier board, and fixing a protective substrate and the sixth substrate with an attaching member.

10. The manufacturing method as claimed in claim 1, further comprising, after the step of disposing a first electronic component on the first peripheral circuit area, the step of disposing a protective layer on the first electronic component.

11. An electronic device, comprising:
a supporting component;
a first panel disposed on the supporting component, wherein the first panel includes a first substrate having a display area and a peripheral circuit area; and
a second panel disposed on the first panel,
wherein the supporting component overlaps the display area and at least a portion of the peripheral circuit area of the first substrate, and the supporting component has a thickness greater than that of the first substrate.

12. The electronic device as claimed in claim 11, wherein the supporting component includes a light-shielding material.

13. The electronic device as claimed in claim 11, wherein a ratio of the thickness of the supporting component and the thickness of the first substrate is greater than or equal to 3 and smaller than or equal to 15.

14. The electronic device as claimed in claim 11, further comprising an attaching member disposed between the first panel and the second panel, wherein the first panel further includes:
a first electronic component disposed on the peripheral circuit area of the first substrate; and
a second substrate disposed on the first substrate,
wherein the attaching member has a first thickness, the second substrate has a second thickness, the first electronic component includes a flexible substrate, the flexible substrate has a third thickness, and the first thickness, the second thickness and the third thickness satisfy:
$$1.5 ≦ ( T 1 + T 2 ) / T 3 ≦ 7.5 ,$$
where T1 represents the first thickness, T2 represents the second thickness, and T3 represents the third thickness.

15. The electronic device as claimed in claim 11, wherein the first panel further includes a first electronic component disposed on the peripheral circuit area of the first substrate, the first electronic component includes a chip and, in a direction perpendicular to a normal direction of the electronic device, the chip is separated from a third substrate of the second panel by a distance.

16. The electronic device as claimed in claim 11, wherein the first panel further includes:
a first electronic component disposed on the peripheral circuit area of the first substrate; and
a protective layer disposed between the second panel and the first electronic component.

17. The electronic device as claimed in claim 11, further comprising: a third panel disposed on the second panel; and a protective substrate disposed on the third panel.

18. The electronic device as claimed in claim 17, wherein the thickness of the supporting component is smaller than or equal to a thickness of the protective substrate.

19. The electronic device as claimed in claim 17, wherein the protective substrate is provided with a light-shielding pattern.

20. The electronic device as claimed in claim 17, wherein the first panel further includes a first electronic component, the second panel further includes a second electronic component, the third panel further includes a third electronic component, and at least two of the first electronic component, the second electronic component and the third electronic component partially overlap or do not overlap with each other.
